(19) United States
(12) Patent Application Publication
(10) Pub. No.: US 2017/0077327 A1
(43) Pub. Date: Mar. 16, 2017

(54) PHOTOELECTRIC CONVERSION ELEMENT, SOLAR CELL, SOLAR CELL MODULE, AND SOLAR POWER GENERATING SYSTEM

(71) Applicant: Kabushiki Kaisha Toshiba, Minato-ku (JP)

(72) Inventors: Hiroki HIRAGA, Saitama (JP); Naoyuki NAKAGAWA, Setagaya (JP); Soichiro SHIBASAKI, Nerima (JP); Hitomi SAITO, Kawaguchi (JP); Miyuki SHIOKAWA, Kawasaki (JP); Mutsuki YAMAZAKI, Yokohama (JP); Kazushige YAMAMOTO, Yokohama (JP)

(73) Assignee: Kabushiki Kaisha Toshiba, Minato-ku (JP)

(21) Appl. No.: 15/254,327

(22) Filed: Sep. 1, 2016

(30) Foreign Application Priority Data
Sep. 15, 2015 (JP) 2015-182338

(51) Int. Cl. H01L 31/032; H01L 31/046; H01L 31/0687; H01L 31/0224

(52) U.S. Cl. CPC H01L 31/0323; H01L 31/022425; H01L 31/046; H01L 31/0687

(57) ABSTRACT

A photoelectric conversion element of an embodiment includes a substrate, a transparent first electrode on the substrate, a second electrode, and a light absorbing layer of a homo-junction type interposed between the first electrode and the second electrode. The light absorbing layer includes a p-type region on the second electrode side and an n-type region on the first electrode side. The n-type region has an n-type dopant. The photoelectric conversion element has a boundary surface between the light absorbing layer on the n-type region side and the first electrode.

### CROSS-REFERENCE TO RELATED APPLICATION

This application is based upon and claims the benefit of priority from Japanese Patent Application No. 2015-182338, filed on Sep. 15, 2015; the entire contents of which are incorporated herein by reference.

### FIELD

Embodiments described herein relate to a photoelectric conversion element, solar cell, solar cell module, and solar power generating system.

### BACKGROUND

Development of compound-based photoelectric conversion elements using semiconductor thin films as light absorbing layers has been in progress. Especially, thin film photoelectric conversion elements including, as a light-absorbing layer, a p-type semiconductor layer having a chalcopyrite structure exhibit high conversion efficiency and are thus already implemented in practical use. Specifically, conversion efficiency of 21.7% is reported with a thin film photoelectric conversion element having a light absorbing layer of Cu(In,Ga)Se₂ containing Cu—In—Ga—Se. Generally, a thin film photoelectric conversion element having a light absorbing layer of a p-type semiconductor layer containing Cu—In—Ga—Se has a structure where, on a soda-lime glass as a substrate, a molybdenum lower electrode, a p-type semiconductor layer, an n-type semiconductor layer, an insulating layer, a transparent electrode, an upper electrode, and an antireflection film are laminated. Here, conversion efficiency η is expressed as η=Voc*Jsc/FF/P*100 with an open circuit voltage Voc, a short circuit current density Jsc, an output factor FF, and an incident power density P.

As apparent from the above, when each one of the open circuit voltage, the short circuit current, and the output factor becomes larger, the conversion efficiency also increases. Theoretically, as a band gap between the light absorbing layer and the n-type semiconductor layer becomes larger, the open circuit voltage increases while the short circuit current density decreases. It is known that a band gap of Cu(In,Ga)Se₂ increases as a Ga concentration increases and that when a ratio of Ga/(In+Ga) is approximately 0.3, the band gap is approximately 1.05 eV. It is known that such a composition ratio results in a photoelectric conversion element with preferable conversion efficiency.

When the Ga concentration increases, the band gap increases up to 1.68 eV (Ga=1). Moreover, replacing Se with S, Cu with Ag, or a group III element with Al or the like can also increase the band gap. With such a photoelectric conversion element material with a wide gap, using transparent component members such as an electrode allows for absorbing a short wavelength region of the sunlight to generate electricity and using transmitted light in a long wavelength region for further generating electricity with a photoelectric conversion element having a small band gap. Overlaying photoelectric conversion elements having a wide gap and a narrow gap allows for implementing a so-called tandem type.

Recently, it is made clear that an alkali metal such as Na and K plays an important role in improving efficiency of a chalcopyrite solar cell. Adding an alkali metal on a p-n boundary surface near a surface during vapor deposition of a light absorbing layer can improve efficiency; however in this method, a cost of vapor deposition step, a cost of materials, or facilities disadvantageously increases. In the related art, an alkali metal diffuses from a glass substrate. The alkali metal accumulates in a light absorbing layer by a large amount before reaching a surface of the light absorbing layer and thus not enough amount of alkali metal reaches the surface. Therefore, reversing a layer structure is considered to allow for adding the alkali metal diffusing from the glass substrate to the p-n boundary surface. Any photoelectric conversion element where a layer structure is actually reversed has a low conversion efficiency of approximately 10%. This is because any of the photoelectric conversion elements is a hetero-junction type and the alkali metal added to an n-type semiconductor layer such as CdS, ZnS, and In₂S₃ degrades performance.

### BRIEF DESCRIPTION OF THE DRAWINGS

FIG. 1 is a schematic cross-sectional view of a photoelectric conversion element of an embodiment;

FIG. 2 is a schematic cross-sectional view of a multi-junction photoelectric conversion element of an embodiment;

FIG. 3 is a schematic cross-sectional view of a photoelectric conversion element of an embodiment;

FIG. 4 is a schematic configuration diagram of a solar cell module of an embodiment;

FIG. 5 is a schematic configuration diagram of a solar power generating system of an embodiment;

FIG. 6 is a picture of a cross-section of a photoelectric conversion element of an example 6 taken by a scanning microscope; and

FIG. 7 is a result of SIMS measurement of the example 6.

### DETAILED DESCRIPTION

A photoelectric conversion element of an embodiment includes a substrate, a transparent first electrode on the substrate, a second electrode, and a light absorbing layer of a homo-junction type interposed between the first electrode and the second electrode. The light absorbing layer includes a p-type region on the second electrode side and an n-type region on the first electrode side. The n-type region has an n-type dopant. The photoelectric conversion element has a boundary surface between the light absorbing layer on the n-type region side and the first electrode.

Hereinafter, a photoelectric conversion element of an embodiment and a solar cell obtained by using the photoelectric conversion element will be described in detail.

### (Photoelectric Conversion Element)

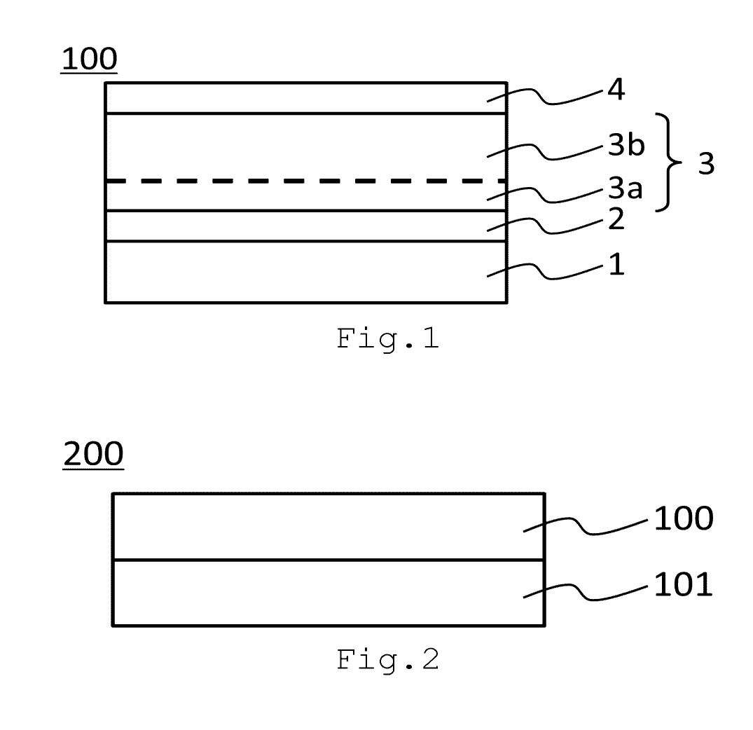

A photoelectric conversion element according to the present embodiment illustrated in the schematic cross-sectional view in FIG. 1 includes a substrate 1, a transparent first electrode 2 on the substrate 1, a second electrode 4, and a light absorbing layer 3 of a homo-junction type interposed between the first electrode and the second electrode. A solar cell of an embodiment is obtained by using the photoelectric conversion element of the embodiment. The photoelectric conversion element of the embodiment is called a super straight type.

Incidentally, the first electrode 2 and the second electrode 4 are connected to conductive extraction electrodes (not shown). Like in FIG. 2, joining a photoelectric conversion element 100 of an embodiment to another photoelectric conversion element 101 results in a multi-junction photoelectric conversion element 200. In FIG. 2, the photoelectric conversion element 100 is used as a top cell on a light-incident side; however, the photoelectric conversion element 100 may be used as a bottom cell. The light absorbing layer of the photoelectric conversion element positioned on the incident light side preferably has a wider gap as compared to that of a light absorbing layer of a photoelectric conversion element positioned not on the incident light side. A band gap of the light absorbing layer having a wide gap may be, for example, 1.2 eV to 1.5 eV. The photoelectric conversion element positioned not on the incident light side may be, for example, one using Si, chalcopyrite, etc. having a band gap of 0.9 eV to 1.2 eV. The multi-junction photoelectric conversion element 200 may include two photoelectric conversion elements joined together like in FIG. 2 or three or more photoelectric conversion elements joined together.

(Substrate 1)

The substrate 1 supports the photoelectric conversion element 100. As the substrate 1 of the embodiment, it is desirable to use glass. Any glass transparent and resistant to high temperature may be used such as soda-lime glass, low alkaline glass, borosilicate glass, and quartz glass. Incidentally, the substrate 1 preferably contains a large amount of alkali metal. Specifically, soda-lime glass is preferable. In the photoelectric conversion element 100 of the embodiment, a main surface of the substrate 1 opposite to the other main surface of the substrate 1 formed with the first electrode 2 is the light-incident surface. The substrate 1 may be provided with an antireflection film or the like (not shown) between the first electrode 2 and the substrate 1 or on the main surface of the substrate 1 opposite to the other surface formed with the first electrode 2.

(First Electrode 2)

The first electrode 2 of the embodiment is a transparent electrode of the photoelectric conversion element 100 and is a transparent conductive film formed on the substrate 1. The first electrode 2 is on the side where light enters. As the first electrode 2, a transparent conductive oxide film such as indium-tin-oxide (ITO), silicon oxide, tin oxide, zinc oxide, or titanium oxide may be used. The first electrode 2 may be a single layer of the conductive oxide film, for example ITO, or may be a lamination film where the conductive oxide films are laminated. Specific examples of the lamination film include a lamination of SnO-ITO-SiO₂ and SnO-AZO-SiO₂ laminated from the light absorbing layer 3 side toward the substrate 1 side. The first electrode 2 can be formed by employing a known method such as sputtering a metal film material on the substrate 1. The thickness of the first electrode 2 is, for example, 100 to 2000 nm.

From the perspective of increasing conversion efficiency, preferably, the first electrode 2 has the following features in addition to conductivity and transparency. For example, a film of SiO₂ as a specific example of the first electrode 2 is formed while the thickness or components thereof are adjusted in order to adjust an amount of alkali metal diffusing from the glass as the substrate 1. Preferably, SiO₂ is disposed between ITO and the light absorbing layer 3. Specifically, the thickness of SiO₂ is, for example, 10 to 1000 nm.

(Light Absorbing Layer 3)

The light absorbing layer 3 of the embodiment is a compound semiconductor layer including an n-type region 3a and a p-type region 3b. The photoelectric conversion element 100 has a boundary surface between the light absorbing layer 3 on the n-type region 3a side and the first electrode 2. The photoelectric conversion element 100 has the boundary surface between a surface of the light absorbing layer 3 on the n-type region 3a side which faces the first electrode 2 and a surface of the first electrode 2 which faces the light absorbing layer 3. Preferably, the photoelectric conversion element 100 has the boundary surface between an entire surface of the light absorbing layer 3 on the n-type region 3a side which faces the first electrode 2 and an entire surface of the first electrode 2 which faces the light absorbing layer 3. Preferably, the light absorbing layer 3 is a compound semiconductor layer including the n-type region 3a and the p-type region 3b. The n-type region 3a is a region of the light absorbing layer 3 caused to be an n-type. The p-type region 3b is a region of the light absorbing layer 3 not caused to be the n-type. The n-type region 3a and the p-type region 3b have the same compound structure except for that they have different conductivity types. The light absorbing layer 3 is of a homo-junction type where the n-type region 3a and the p-type region 3b are homozygously joined together. On the main surface of the light absorbing layer 3 on the first electrode 2 side, the n-type region 3a exists. On the main surface of the light absorbing layer 3 on the second electrode 4 side, the p-type region 3b exists.

As the light absorbing layer 3, a compound semiconductor layer having a chalcopyrite structure, a stannite structure, or a kesterite structure such as CIGS, CGS, CIT, or CZTS containing a group Ib element, a group IIIb element, and a group VIb element. The thickness of the light absorbing layer 3 is, for example, 500 to 3000 nm. As the group Ib element, Cu (copper), Ag (silver), or Cu and Ag is preferable. As the group IIIb element, at least one element selected from the group consisting of; the group consisting of; Al, In, and Ga are preferable. As the group VIb element, at least one element selected from the group consisting of; O, S, Se, and Te are preferable. It is more preferable that at least Se is contained.

Specifically, as the light absorbing layer 3, compound semiconductors such as Cu(In,Ga) (S,Se)₂, Cu(In,Ga) (Se,Te)₂, Cu(In,Ga)₃(Se,Te)₅, Cu(Al,Ga,In)Se₂, and Cu₂ZnSnS₄, more specifically, Cu(In,Ga)Se₂, CuInSe₂, CuInTe₂, CuGaSe₂, and CuIn₃Te₅ can be used at an arbitrary composition ratio thereof. Changing the composition ratio of the light absorbing layer 3 can change the band gap.

(N-Type Region 3a)

The n-type region 3a of the embodiment is a semiconductor region of an n-type. The n-type region 3a is a layer-shaped region formed between the p-type region 3b and the first electrode 2. Preferably, the n-type region 3a is an n-type semiconductor controlled of a Fermi level to allow for obtaining a photoelectric conversion element having a high open circuit voltage. The thickness of the n-type region 3a is, for example, 10 to 500 nm. Preferably, the n-type region 3a contains an n-type dopant at a concentration of 10²⁰ to 10²¹ atoms/cm³.

(p-Type Region 3b)

The p-type region 3b of the embodiment is a semiconductor region of a p-type. The p-type region 3b is a layer-shaped region formed between the second electrode 4 and the n-type region 3a. The thickness of the p-type region 3b is obtained by subtracting the thickness of the n-type region 3a from the thickness of the light absorbing layer 3. Preferably, the n-type region 3a and the p-type region 3b have a pn-junction but no boundary surface.

The n-type dopant (at least one element selected from the group consisting of; Cd, Zn, and Mg) of the light absorbing layer 3 can be confirmed by the following method. Divide the main surface of the first electrode 2 on the substrate 1 side (the boundary surface between the substrate 1 and the first electrode 2 in FIG. 1) into four square regions having equivalent areas. The total of five points including four points in the centers of the four divided regions and one point in the center of the main surface are subjected to etching while analyzing the five points by secondary ion mass spectrometry (SIMS). An average value of measurement values of the five points is regarded as an analysis value. The analysis is performed from the first electrode 2 side. The boundary surface between the first electrode 2 and the light absorbing layer 3 is assumed to be positioned at a depth where the concentration of the group IIIb element in the light absorbing layer 3 first reaches one-tenth or more of the maximum value of the concentrations obtained in the analysis. The thickness of the light absorbing layer 3 is a distance between a depth where, while SIMS analysis is further performed along with etching, the concentration of the group IIIb element in the light absorbing layer 3 reaches less than one-tenth of the maximum value of the concentrations obtained in the analysis and the boundary surface between the first electrode 2 and the light absorbing layer 3. Here, the thickness of the light absorbing layer 3 is denoted as d. The concentration of the n-type dopant at a depth of 0.01d from the boundary surface between the first electrode 2 and the light absorbing layer 3 is denoted as X (atoms/cm³). Furthermore, the concentration of the n-type dopant at a depth of 0.5d from the boundary surface between the first electrode 2 and the light absorbing layer 3 is denoted as Y (atoms/cm³). The concentration of the n-type dopant at a depth of 0.1d from the boundary surface between the first electrode 2 and the light absorbing layer 3 is further denoted as Z (atoms/cm³). From the perspective that it is preferable that a dopant is contained more near a surface of the first electrode in order to form a preferable pn-junction, X and Y preferably satisfy the relation of X/Y>10. More preferably, X/Y>100 is satisfied. Moreover, it is further preferable that X and Z satisfy the relation of X/Z>2. When a component of the n-type semiconductor such as CdS remains as a layer without completely diffusing, this results in a pn-hetero-junction with efficiency not quite high. Incidentally, to confirm that CdS remains as a layer, identification may be performed by a method such as TEM-EDX. Confirmation can be made with existence of Cd and S in the same region.

It is also preferable that the light absorbing layer 3 contains an alkali metal such as Na and K from the perspective of improving conversion efficiency. It is preferable that the maximum concentration of the alkali metal in the light absorbing layer 3 is within 10¹⁹ atoms/cm³ to 10²² atoms/cm³ since the photoelectric conversion element 100 having high conversion efficiency can be obtained. The concentration of the alkali metal contained in the light absorbing layer 3 is measured by a similar method to that of the n-type dopant.

Methods to form the light absorbing layer 3 of the embodiment include thin film forming methods such as sputtering, a vapor deposition method, and a selenization and sulfurization method, for example. Next, a method to form the n-type region 3a will be described. As one method, before forming the light absorbing layer 3, a thin film containing the n-type dopant is formed on the first electrode 2 and then the light absorbing layer 3 is formed on the thin film containing the n-type dopant. The n-type dopant is thereby allowed to diffuse in a region of the light absorbing layer 3, which is originally a p-type, on the first electrode 2 side by a heat diffusion method, thereby forming the n-type region 3a. As another method, a compound semiconductor layer is formed while the n-type dopant is added onto the first electrode 2 by a vapor deposition method, a sputtering method, a selenization and/or sulfurization method, a sintering method, or the like. Adding the n-type dopant is halted at a desired timing to form the compound semiconductor layer, thereby forming the light absorbing layer 3. The n-type dopant is a metal containing an element such as Cd, Zn, and Mg or a compound containing the element.

The thin film containing the n-type dopant is formed by a CVD method, a spin coating method, a liquid phase growth method, a dipping method, a vapor deposition method, an application method, a sputtering method, or the like. The thin film containing the n-type dopant may be, specifically, a metal film such as Cd, Zn, Mg or a compound containing a metal element as a dopant and a group VI element not resulting in reduced efficiency even when diffuses in the main body of the light absorbing layer such as ZnS, Zn(O_{α}S_{1-α}), (Zn_{β}Mg_{1-β})(O_{α}S_{1-α}), (Zn_{β}Cd_{γ}Mg_{1-β-γ})(O_{α}S_{1-α}), CdS, Cd(O_{α}S_{1-α}), (Cd_{β}Mg_{1-β})S, (Cd_{β}Mg_{1-β})(O_{α}S_{1-α}), In₂S₃, In₂(O_{α}S_{1-α}), CaS, Ca(O_{α}S_{1-α}), SrS, Sr(O_{α}S_{1-α}), ZnSe, and ZnIn_{2-δ}Se_{4-ε} (each of α, β, γ, δ, and ε preferably satisfies 0<α<1, 0<β<1, 0<γ<1, 0<δ<2, 0<ε<4, and β+γ<1).

When the compound semiconductor layer is formed while the n-type dopant is added onto the first electrode 2, methods to form the light absorbing layer 3 containing the n-type dopant include a sputtering method, a vapor deposition method, selenization and/or sulfurization method, a sintering method, a chemical vapor deposition method, a liquid phase growth method, an application method, or the like. As an example, further using Cd as a sputtering target, a film of Cuₓ(In_{1-y}Ga_{y}) (Se_{1-z}S_{z})₂ (0.5≦x≦1, 0≦y≦1, and 0≦z≦1) containing the n-type region 3a doped with Cd at a concentration of 10¹⁹ to 10²¹ atoms/cm³ can be formed to a film thickness of approximately 10 to 500 nm.

(Intermediate Layer 5)

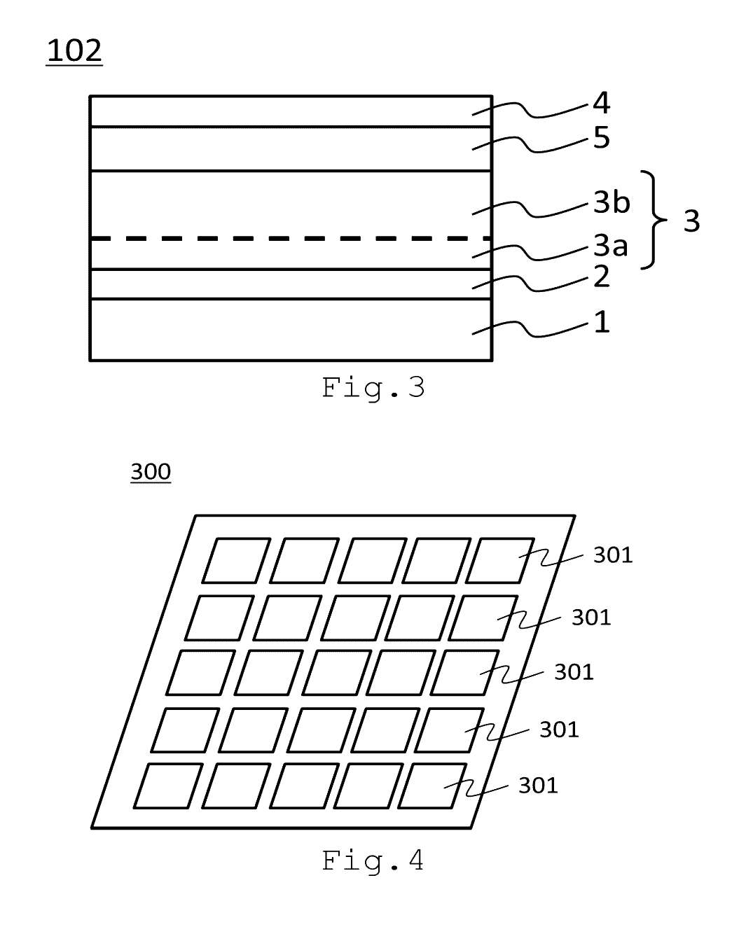

In an embodiment, like in a photoelectric conversion element 102 illustrated in the schematic cross-sectional view in FIG. 3, an intermediate layer 5 may be further included between a light absorbing layer 3 and a second electrode 4. The intermediate layer 5 delivers positive holes to the second electrode 4, for example. The intermediate layer 5 is further expected to suppress and/or mitigate damages to the light absorbing layer 3 upon forming the second electrode 4 caused by sputtering or the like. The intermediate layer 5 includes an oxide film, a metal film, or the like. Specifically, the intermediate layer 5 includes an oxide containing an element or compound selected from the group consisting of; ZnTe, molybdenum, vanadium, nickel, copper, titanium, tungsten, chromium, tantalum, and cobalt, a metal film containing the element, or the like having a thickness of 100 nm or less. When the intermediate layer 5 is a layer of the oxide, typically, the thickness of the intermediate layer 5 is preferably 100 nm or less. When the intermediate layer 5 is the metal film, typically, the thickness of the intermediate layer 5 is preferably 10 nm or less. Methods to form the p-contact layer include a CVD method, a spin coating method, a dipping method, a vapor deposition method, a sputtering method, a spraying method, an application method, or the like.

The intermediate layer 5 may be included or be omitted. When enough characteristics of photoelectric conversion element is obtained depending on a type of layer used for the second electrode 4 or a method for forming the second electrode 4, the intermediate layer 5 is suitably omitted. For example, when a film of Au is formed or when a film of indium oxide doped with Zn, which can be formed by sputtering at a low voltage and a room temperature, is formed on the light absorbing layer 3 as the second electrode 4, the intermediate layer 5 is suitably omitted.

(Second Electrode 4)

The second electrode 4 of the embodiment interposes the light absorbing layer 3 with the first electrode 2. The second electrode 4 exists on the opposite side to the side of the light absorbing layer 3 where the first electrode 2 is formed. The second electrode 4 is a film including a metal film or a transparent conductive film. When the photoelectric conversion element 100 is used in a multi-junction photoelectric conversion element but not as a bottom cell, the second electrode 4 is preferably a transparent electrode. Specifically, the second electrode 4 may be a metal film containing at least one metal selected from the group consisting of; gold, nickel, silver, copper, molybdenum, tungsten, or the like, a transparent conductive film such as conductive paste containing carbon, silver, or nanoparticles, or a complex oxide represented by ZnO:Al (alumina-containing zinc oxide) containing 2 wt % to 20% of alumina (Al₂O₃), ZnO:B (B-doped zinc oxide) containing 2 wt % to 20% of B derived from diborane as a dopant, In₂O₃:Sn (tin oxide-containing indium oxide) containing 2 wt % to 25% of tin oxide (SnO), or the like. The second electrode 4 is formed by vapor deposition, sputtering, or the like. Preferably, the layer has high transmittance and conductivity.

In the photoelectric conversion element of the embodiment, a p-n layer structure of a chalcopyrite photoelectric conversion element of a homo-junction type is reversed and thus the photoelectric conversion element can be easily configured, which is quite useful from industrial perspectives. Forming, on the first electrode 2 in advance, the film of a compound containing an element to form the n-type dopant allows the dopant to diffuse by heat upon preparation of the light absorbing layer 3, thereby allowing for forming the p-n homo-junction. Therefore, the photoelectric conversion element with the reversed layer structure can be obtained. Furthermore, using the alkali metal diffusing from the glass substrate allows for obtaining a photoelectric conversion element having a higher conversion efficiency.

(Solar Cell Module)

A solar cell of an embodiment can be used as a power generating element in a solar cell module. The solar cell of the embodiment refers to a solar cell where the photoelectric conversion element of the embodiment receives light and thereby generates electricity. The generated power may be consumed by a load electrically connected to the solar cell or may be stored in a battery electrically connected to the solar cell.

A solar cell module of an embodiment may be a member where the plurality of solar cells are connected in series, in parallel, or in series and parallel or have a structure where a single cell is fixed to a support member such as glass. The solar cell module may be provided with a light condensing body and thereby configured to convert light receiving on an area larger than an area of the solar cell into power.

FIG. 4 illustrates a schematic configuration diagram of a solar cell module 300 where a plurality of solar cells 301 are arrayed by five cells in the horizontal direction and by five cells in the vertical direction. In the solar cell module 300 in FIG. 4, connection wiring is omitted. As described above, the plurality of solar cells 301 is preferably connected in series, in parallel, or in series and parallel. Preferably, the photoelectric conversion element 100 of the embodiment, that is, a solar cell, is used as the solar cell 301. Alternatively, a solar cell of a multi-junction photoelectric conversion element where the photoelectric conversion element 100 of the embodiment and another photoelectric conversion element 200 are joined together may be preferably used as the solar cell 301. Further alternatively, the solar cell module 300 of the embodiment may employ a module structure where a module using the photoelectric conversion element 100 of the embodiment and a module using the other photoelectric conversion element 101 are overlaid. Other structures for improving conversion efficiency may be preferably employed. In the solar cell module 300 of the embodiment, preferably, the solar cell 301 is included on a light-receiving surface side since the solar cell 301 includes a photoelectric conversion layer having a wide band gap.

(Solar Power Generating System)

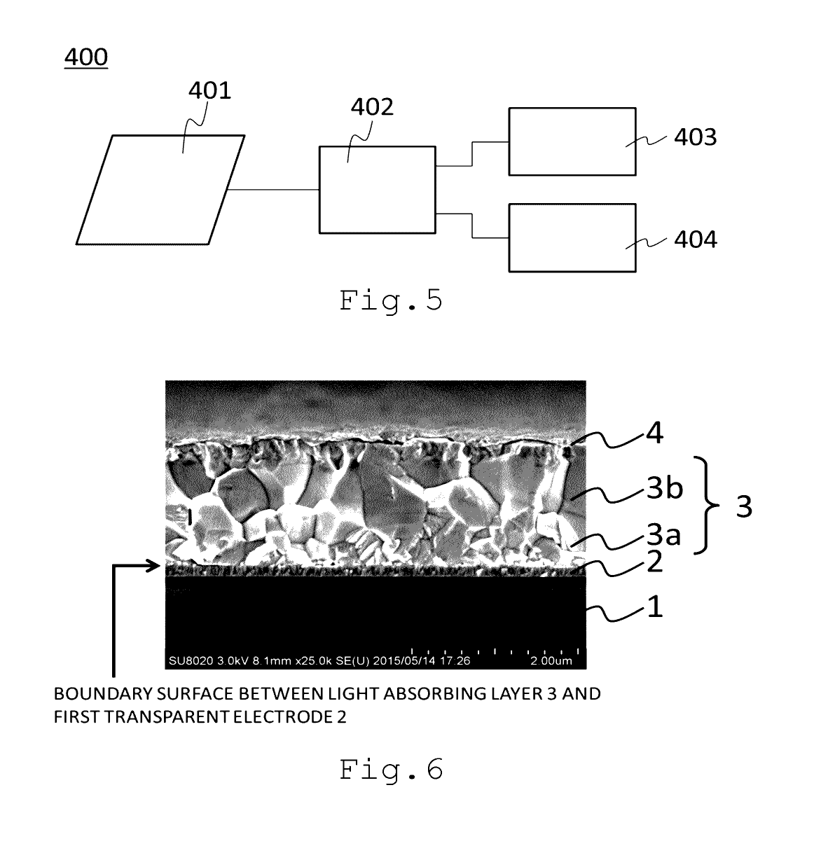

A solar cell module 300 of an embodiment can be used as a power generator to generate electricity in a solar power generating system. A solar power generating system of an embodiment generates electricity using a solar cell module. Specifically, the solar power generating system includes a solar cell module to generate electricity, a means to convert the generated electricity into power, and a battery means to store the generated electricity or a load to consume the generated electricity. FIG. 5 illustrates a schematic configuration diagram of a solar power generating system 400 of an embodiment. The solar power generating system in FIG. 5 includes a solar cell module 401 (300), a converter 402, a battery 403, and a load 404. Either the battery 403 or the load 404 may be omitted. The load 404 may be configured to enable use of electric energy stored in the battery 403. The converter 402 is a device including a circuit or an element to perform power conversion such as voltage transformation or DC/AC conversion such as a DC-DC converter, a DC-AC converter, or an AC-AC converter. The converter 402 may employ a suitable configuration according to a generation voltage or a configuration of the battery 403 or the load 404.

The solar cell 301, of the solar cell module 300, receiving light generates electricity. The electric energy is converted by the converter 402 and stored in the battery 403 or consumed by the load 404. It is preferable to provide, to the solar cell module 401, a sunlight tracking driving device to direct the solar cell module 401 toward the sun at all times, a light condensing body to condense sunlight, a device to improve power generation efficiency, or the like.

Preferably, the solar power generating system 400 is used for immovable property such as a residence, a commercial facility, or a plant or for movable property such as a vehicle, an airplane, or an electronics. Using the photoelectric conversion element of the embodiment having excellent conversion efficiency in the solar cell module 401 is expected to increase an amount of electricity generated.

Hereinafter, the photoelectric conversion element of the embodiments will be described with examples.

### Example 1

A lower electrode of a film shape containing SiO₂-ITO-SnO₂ was formed on a soda-lime glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, In, Ga, and Se. The thickness of the layer was set to approximately 2200 nm. As a result, CdS diffused in the p-type light absorbing layer by heat diffusion, thereby allowing a region thereof near the lower electrode to be an n-type. An upper electrode of Au was then formed to a thickness of 100 nm. A band gap of the light absorbing layer was 1.15 eV while conversion efficiency of the photoelectric conversion element was 18%. The transmittance was 0%. A profile of Na concentrations was examined by SIMS. A portion containing 10²¹ atoms/cm³ of Na was confirmed in the light absorbing layer. Doping concentrations of Cd in the light absorbing layer were also measured by SIMS. The Cd concentration at a depth of 22 nm from a boundary surface between the first electrode and the light absorbing layer was 1×10²¹ (atoms/cm³). The Cd concentration at a depth of 1100 nm from the boundary surface between the first electrode and the light absorbing layer was 1×10¹⁹ (atoms/cm³).

### Example 2

A lower electrode of a film shape containing SiO₂-ITO-SnO₂ was formed on a soda-lime glass substrate of 16 mm in length, 12.5 mm in width, and 1.8 mm in thickness by sputtering in an Ar air flow. The thickness of the lower electrode was set to approximately 250 nm. A film of ZnS was grown on the lower electrode to the thickness of 50 nm by a solution growth method, whereon a p-type light absorbing layer was formed by a vapor deposition method at an arbitrary ratio of Cu, In, Ga, and Se. The thickness of the layer was set to approximately 2200 nm. As a result, ZnS diffused in the p-type light absorbing layer by heat diffusion, thereby allowing a region thereof near the lower electrode to be an n-type. An upper electrode of Au was then formed to a thickness of 100 nm. A band gap of the light absorbing layer was 1.15 eV while conversion efficiency of the photoelectric conversion element was 16%. The transmittance was 0%. A profile of Na concentrations was examined by SIMS. A portion containing 10²¹ atoms/cm³ of Na was confirmed in the light absorbing layer. Doping concentrations of Cd in the light absorbing layer were also measured by SIMS. The Cd concentration at a depth of 22 nm from a boundary surface between the first electrode and the light absorbing layer was 1×10²¹ (atoms/cm³). The Cd concentration at a depth of 1100 nm from the boundary surface between the first electrode and the light absorbing layer was 1×10¹⁹ (atoms/cm³).

### Example 3

A lower electrode of a film shape containing SiO₂-ITO-SnO₂ was formed on a soda-lime glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, CdS diffused in the p-type light absorbing layer by heat diffusion, thereby allowing a region thereof near the lower electrode to be an n-type. Thereafter, molybdenum oxide was subjected to vapor deposition to a thickness of 30 nm. As an upper electrode, indium oxide doped with zinc by 10% was formed to a thickness of 100 nm. A band gap of the light absorbing layer was 1.68 eV while conversion efficiency of the photoelectric conversion element was 12% and the transmittance was 75%. Conversion efficiency of a single crystal Si solar cell shielded from light by this photoelectric conversion element was 9.2%. Conversion efficiency of this single crystal Si solar cell without shielding light is 20%. A profile of Na concentrations was examined by SIMS. A portion containing 10²¹ atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²¹ (atoms/cm³). The Cd concentration at a depth of 750 nm from the boundary surface between the first electrode and the light absorbing layer was 1×10¹⁹ (atoms/cm³).

### Example 4

A lower electrode of a film shape containing SiO₂-ITO-SnO₂ was formed on a soda-lime glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, CdS diffused in the p-type light absorbing layer by heat diffusion, thereby allowing a region thereof near the lower electrode to be an n-type. Thereafter, as an upper electrode, indium oxide doped with zinc by 10% was formed to a thickness of 100 nm. A band gap of the light absorbing layer was 1.68 eV while conversion efficiency of the photoelectric conversion element was 11%. The transmittance was 80%. Conversion efficiency of a single crystal Si solar cell shielded from light by this photoelectric conversion element was 10.3%. Conversion efficiency of this single crystal Si solar cell without shielding light is 20%. A profile of Na concentrations was examined by SIMS. A portion containing 10²¹ atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²¹ (atoms/cm³). The Cd concentration at a depth of 750 nm from the boundary surface between the first electrode and the light absorbing layer was 1×10¹⁹ (atoms/cm³).

### Example 5

A lower electrode of a film shape containing SiO₂-ITO-SnO₂ was formed on a soda-lime glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, CdS diffused in the p-type light absorbing layer by heat diffusion, thereby allowing a region thereof near the lower electrode to be an n-type. Thereafter, Au was subjected to vapor deposition to a thickness of 5 nm as a p-contact layer. As an upper electrode, indium oxide doped with zinc by 10% was formed to a thickness of 100 nm. A band gap of the light absorbing layer was 1.68 eV while conversion efficiency of the photoelectric conversion element was 13% and the transmittance was 65%. Conversion efficiency of a single crystal Si solar cell shielded from light by this photoelectric conversion element was 8.2%. Conversion efficiency of this single crystal Si solar cell without shielding light is 20%. A profile of Na concentrations was examined by SIMS. A portion containing 10²¹ atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²¹ (atoms/cm³). The Cd concentration at a depth of 750 nm from the boundary surface between the first electrode and the light absorbing layer was 1×10¹⁹ (atoms/cm³).

### Example 6

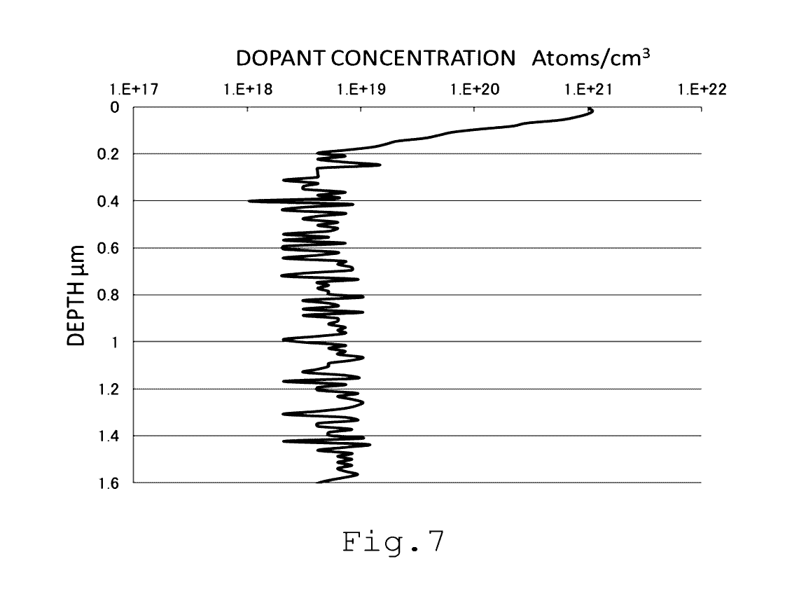

A lower electrode of a film shape containing SiO₂-ITO-SnO₂ was formed on a soda-lime glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, CdS diffused in the p-type light absorbing layer by heat diffusion, thereby allowing a region thereof near the lower electrode to be an n-type. As an upper electrode, Au was then subjected to vapor deposition to a thickness of 50 nm. A band gap of the light absorbing layer was 1.68 eV while conversion efficiency of the photoelectric conversion element was 13% and the transmittance was 0%. A profile of Na concentrations was examined by SIMS. A portion containing 10²¹ atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²¹ (atoms/cm³). The Cd concentration at a depth of 750 nm from the boundary surface between the first electrode and the light absorbing layer was 1×10¹⁹ (atoms/cm³). FIG. 6 is a picture of the photoelectric conversion element of the example 6 taken by a scanning microscope and FIG. 7 is a result of SIMS measurement of the example 6. Observation by a scanning electron microscope (SEM) has clarified that the CdS layer of 50 nm prepared before forming the light absorbing layer has diffused due to heat upon preparation of the light absorbing layer and thus the CdS layer has disappeared.

### Example 7

A lower electrode of a film shape containing SiO₂-ITO-SnO₂ was formed on a quartz glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, CdS diffused in the p-type light absorbing layer by heat diffusion, thereby allowing a region thereof near the lower electrode to be an n-type. Thereafter, molybdenum oxide was subjected to vapor deposition to a thickness of 30 nm. As an upper electrode, indium oxide doped with zinc by 10% was formed to a thickness of 100 nm. A band gap of the light absorbing layer was 1.68 eV while conversion efficiency of the photoelectric conversion element was 5% and the transmittance was 75%. Conversion efficiency of a single crystal Si solar cell shielded from light by this photoelectric conversion element was 9.2%. Conversion efficiency of this single crystal Si solar cell without shielding light is 20%. Since the quartz substrate does not contain an alkali metal such as Na or K, this photoelectric conversion element had a low conversion efficiency. A profile of Na concentrations was examined by SIMS. However, no Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²¹ (atoms/cm³). The Cd concentration at a depth of 750 nm from the boundary surface between the first electrode and the light absorbing layer was 1×10¹⁹ (atoms/cm³).

### Example 8

A lower electrode of a film shape containing SiO₂-ITO was formed on a soda-lime glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, CdS diffused in the p-type light absorbing layer by heat diffusion, thereby allowing a region thereof near the lower electrode to be an n-type. Thereafter, molybdenum oxide was subjected to vapor deposition to a thickness of 30 nm. As an upper electrode, indium oxide doped with zinc by 10% was formed to a thickness of 100 nm. A band gap of the light absorbing layer was 1.68 eV while conversion efficiency of the photoelectric conversion element was 4% and the transmittance was 75%. Conversion efficiency of a single crystal Si solar cell shielded from light by this photoelectric conversion element was 9.2%. Conversion efficiency of this single crystal Si solar cell without shielding light is 20%. Since the lower electrode containing SiO-ITO may easily transmit an alkali metal such as Na or K from the glass substrate to the photoelectric conversion element, a large amount of alkali metal is contained in the photoelectric conversion element. Therefore, this photoelectric conversion element had low conversion efficiency. A profile of Na concentrations was examined by SIMS. A portion containing 10²⁴ atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²² (atoms/cm³). The Cd concentration at a depth of 750 nm from the boundary surface between the first electrode and the light absorbing layer was 1×10¹⁹ (atoms/cm³).

### Example 9

A lower electrode of a film shape containing SiO₂-ITO-SnO₂ was formed on a soda-lime glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, CdS diffused in the p-type light absorbing layer by heat diffusion, thereby allowing a region thereof near the lower electrode to be an n-type. Thereafter, as an upper electrode, indium oxide doped with zinc by 10% was formed to a thickness of 100 nm. A band gap of the light absorbing layer was 1.68 eV while conversion efficiency of the photoelectric conversion element was 11%. The transmittance was 80%. Conversion efficiency of a single crystal Si solar cell shielded from light by this photoelectric conversion element was 10.3%. Conversion efficiency of this single crystal Si solar cell without shielding light is 20%.

A profile of Na concentrations was examined by SIMS. A portion containing, at the maximum, 10²¹ atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²¹ (atoms/cm³). The Cd concentration at a depth of 750 nm from the boundary surface between the first electrode and the light absorbing layer was 1×10¹⁹ (atoms/cm³).

### Comparative Example 1

A lower electrode of a film shape containing SiO₂-ITO was formed on a soda-lime glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The temperature of forming the film and/or the layer was set at approximately 300° C., thereby suppressed diffusion of CdS to CGS. A layer of CdS thus partially remained between the light absorbing layer and the lower electrode. The thickness of the layer was set to approximately 1500 nm. As a result, a p-n hetero-junction of CdS and CGS was formed. Thereafter, molybdenum oxide was subjected to vapor deposition to a thickness of 30 nm. As an upper electrode, indium oxide doped with zinc by 10% was formed to a thickness of 100 nm. A band gap of the light absorbing layer was 1.68 eV while conversion efficiency of the photoelectric conversion element was 5% and the transmittance was 70%. This shows that the hetero-junction has a low conversion efficiency. A profile of Na concentrations was examined by SIMS. A portion containing, at the maximum, 10²¹ atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²⁴ (atoms/cm³). The Cd concentration at a depth of 750 nm from the boundary surface between the first electrode and the light absorbing layer was 1×10²² (atoms/cm³).

### Example 10

A lower electrode of a film shape containing ITO-SnO₂—TiO₂ was formed on a soda-lime glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, CdS diffused in the p-type light absorbing layer by heat diffusion, thereby allowing a region thereof near the lower electrode to be an n-type. Thereafter, as an upper electrode, indium oxide doped with zinc by 10% was formed to a thickness of 100 nm. A band gap of the light absorbing layer was 1.68 eV while conversion efficiency of the photoelectric conversion element was 7%. The transmittance was 77%. Conversion efficiency of a single crystal Si solar cell shielded from light by this photoelectric conversion element was 9.3%. Conversion efficiency of this single crystal Si solar cell without shielding light is 20%. A profile of Na concentrations was examined by SIMS. A portion containing 10¹⁸ atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²¹ (atoms/cm³). The Cd concentration at a depth of 750 nm from the boundary surface between the first electrode and the light absorbing layer was 1×10¹⁹ (atoms/cm³).

### Example 11

A lower electrode of a film shape containing SiO₂-ITO-SnO₂—TiO₂ was formed on a soda-lime glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, CdS diffused in the p-type light absorbing layer by heat diffusion, thereby allowing a region thereof near the lower electrode to be an n-type. Thereafter, as an upper electrode, indium oxide doped with zinc by 10% was formed to a thickness of 100 nm. A band gap of the light absorbing layer was 1.68 eV while conversion efficiency of the photoelectric conversion element was 8%. The transmittance was 77%. Conversion efficiency of a single crystal Si solar cell shielded from light by this photoelectric conversion element was 9.3%. Conversion efficiency of this single crystal Si solar cell without shielding light is 20%. A profile of Na concentrations was examined by SIMS. A portion containing 10¹⁸ atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²¹ (atoms/cm³). The Cd concentration at a depth of 750 nm from the boundary surface between the first electrode and the light absorbing layer was 1×10¹⁹ (atoms/cm³).

### Example 12

A lower electrode of a film shape containing ITO was formed on a soda-lime glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, CdS diffused in the p-type light absorbing layer by heat diffusion, thereby allowing a region thereof near the lower electrode to be an n-type. Thereafter, as an upper electrode, indium oxide doped with zinc by 10% was formed to a thickness of 100 nm. A band gap of the light absorbing layer was 1.68 eV while conversion efficiency of the photoelectric conversion element was 4%. The transmittance was 75%. Conversion efficiency of a single crystal Si solar cell shielded from light by this photoelectric conversion element was 9.2%. Conversion efficiency of this single crystal Si solar cell without shielding light is 20%. A profile of Na concentrations was examined by SIMS. A portion containing 10²² atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²¹ (atoms/cm³). The Cd concentration at a depth of 750 nm from the boundary surface between the first electrode and the light absorbing layer was 1×10¹⁹ (atoms/cm³).

### Example 13

A lower electrode of a film shape containing SiO₂-ITO-SnO₂ was formed on a soda-lime glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, CdS diffused in the p-type light absorbing layer by heat diffusion, thereby allowing a region thereof near the lower electrode to be an n-type. Thereafter, vanadium oxide was subjected to vapor deposition to a thickness of 30 nm. As an upper electrode, indium oxide doped with zinc by 10% was formed to a thickness of 100 nm. A band gap of the light absorbing layer was 1.68 eV while conversion efficiency of the photoelectric conversion element was 9% and the transmittance was 75%. Conversion efficiency of a single crystal Si solar cell shielded from light by this photoelectric conversion element was 9.2%. Conversion efficiency of this single crystal Si solar cell without shielding light is 20%. A profile of Na concentrations was examined by SIMS. A portion containing 10²⁰ atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²¹ (atoms/cm³). The Cd concentration at a depth of 750 nm from the boundary surface between the first electrode and the light absorbing layer was 1×10¹⁹ (atoms/cm³).

### Example 14

A lower electrode of a film shape containing SiO₂-ITO-SnO₂ was formed on a soda-lime glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, CdS diffused in the p-type light absorbing layer by heat diffusion, thereby allowing a region thereof near the lower electrode to be an n-type. Thereafter, Ag was subjected to vapor deposition to a thickness of 30 nm. As an upper electrode, indium oxide doped with zinc by 10% was formed to a thickness of 100 nm. A band gap of the light absorbing layer was 1.68 eV while conversion efficiency of the photoelectric conversion element was 12% and the transmittance was 0%. A profile of Na concentrations was examined by SIMS. A portion containing 10²⁰ atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²¹ (atoms/cm³). The Cd concentration at a depth of 750 nm from the boundary surface between the first electrode and the light absorbing layer was 1×10¹⁹ (atoms/cm³).

### Example 15

A lower electrode of a film shape containing SiO₂-ITO-SnO₂ was formed on a soda-lime glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, CdS diffused in the p-type light absorbing layer by heat diffusion, thereby allowing a region thereof near the lower electrode to be an n-type. Thereafter, as an upper electrode, zinc oxide doped with B by 5% was formed to a thickness of 100 nm. A band gap of the light absorbing layer was 1.68 eV while conversion efficiency of the photoelectric conversion element was 11%. The transmittance was 75%. Conversion efficiency of a single crystal Si solar cell shielded from light by this photoelectric conversion element was 9.2%. Conversion efficiency of this single crystal Si solar cell without shielding light is 20%. A profile of Na concentrations was examined by SIMS. A portion containing 10²⁰ atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²¹ (atoms/cm³). The Cd concentration at a depth of 750 nm from the boundary surface between the first electrode and the light absorbing layer was 1×10¹⁹ (atoms/cm³).

### Example 16

A lower electrode of a film shape containing SiO₂-ITO-SnO₂ was formed on a soda-lime glass substrate of 16 mm in length, 12.5 mm in width, and 1.8 mm in thickness by sputtering in an Ar air flow. The thickness of the lower electrode was set to approximately 250 nm. A p-type light absorbing layer was formed on the lower electrode by a vapor deposition method at an arbitrary ratio of Cu, Ga, and Se. Incidentally, when forming the layer on the lower electrode, Cd was further used as a target of vapor deposition, thereby allowed a light absorbing layer on the lower electrode side to be doped with Cd. The thickness of the layer was set to approximately 1500 nm. Using Cd when forming the light absorbing layer on the lower electrode side allowed the light absorbing layer near the lower electrode to be an n-type. Thereafter, as an upper electrode, indium oxide doped with zinc by 10% was formed to a thickness of 100 nm. A band gap of the light absorbing layer was 1.68 eV while conversion efficiency of the photoelectric conversion element was 9%. The transmittance was 75%. Conversion efficiency of a single crystal Si solar cell shielded from light by this photoelectric conversion element was 9.2%. Conversion efficiency of this single crystal Si solar cell without shielding light is 20%. A profile of Na concentrations was examined by SIMS. A portion containing 10²⁰ atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²⁴ (atoms/cm³). The Cd concentration at a depth of 750 nm from the boundary surface between the first electrode and the light absorbing layer was 1×10²² (atoms/cm³).

### Example 17

A lower electrode of a film shape containing SiO₂-ITO-SnO₂ was formed on a soda-lime glass substrate of 16 mm in length, 12.5 mm in width, and 1.8 mm in thickness by sputtering in an Ar air flow. The thickness of the lower electrode was set to approximately 250 nm. A film of In₂S₃ was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, In₂S₃ diffused in the p-type light absorbing layer by heat diffusion, thereby allowing a region thereof near the lower electrode to be an n-type. Thereafter, as an upper electrode, indium oxide doped with zinc by 10% was formed to a thickness of 100 nm. A band gap of the light absorbing layer was 1.68 eV while conversion efficiency of the photoelectric conversion element was 9%. The transmittance was 75%. Conversion efficiency of a single crystal Si solar cell shielded from light by this photoelectric conversion element was 9.2%. Conversion efficiency of this single crystal Si solar cell without shielding light is 20%. A profile of Na concentrations was examined by SIMS. A portion containing 10²⁰ atoms/cm³ of Na was confirmed in the light absorbing layer. Doping concentrations of In in the light absorbing layer were also measured by SIMS. The In concentration at a depth of 15 nm from a boundary surface between the first electrode and the light absorbing layer was 1×10²¹ (atoms/cm³). The In concentration at a depth of 750 nm from the boundary surface between the first electrode and the light absorbing layer was 1×10¹⁹ (atoms/cm³).

### Example 18

A lower electrode of a film shape containing SiO₂-ITO-SnO₂ was formed on a soda-lime glass substrate of 16 mm in length, 12.5 mm in width, and 1.8 mm in thickness by sputtering in an Ar air flow. The thickness of the lower electrode was set to approximately 250 nm. A film of ZnS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, ZnS diffused in the p-type light absorbing layer by heat diffusion, thereby allowing a region thereof near the lower electrode to be an n-type. Thereafter, as an upper electrode, indium oxide doped with zinc by 10% was formed to a thickness of 100 nm. A band gap of the light absorbing layer was 1.68 eV while conversion efficiency of the photoelectric conversion element was 9%. The transmittance was 75%. Conversion efficiency of a single crystal Si solar cell shielded from light by this photoelectric conversion element was 9.2%. Conversion efficiency of this single crystal Si solar cell without shielding light is 20%. A profile of Na concentrations was examined by SIMS. A portion containing 10²⁰ atoms/cm³ of Na was confirmed in the light absorbing layer. Doping concentrations of Zn in the light absorbing layer were also measured by SIMS. The Zn concentration at a depth of 15 nm from a boundary surface between the first electrode and the light absorbing layer was 1×10²² (atoms/cm³). The Zn concentration at a depth of 750 nm from the boundary surface between the first electrode and the light absorbing layer was 1×10¹⁹ (atoms/cm³).

### Example 19

A lower electrode of a film shape containing SiO₂-ITO-SnO₂ was formed on a soda-lime glass substrate of 16 mm in length, 12.5 mm in width, and 1.8 mm in thickness by sputtering in an Ar air flow. The thickness of the lower electrode was set to approximately 250 nm. A film of ZnCdS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, ZnCdS diffused in the p-type light absorbing layer by heat diffusion, thereby allowing a region thereof near the lower electrode to be an n-type. Thereafter, as an upper electrode, indium oxide doped with zinc by 10% was formed to a thickness of 100 nm. A band gap of the light absorbing layer was 1.68 eV while conversion efficiency of the photoelectric conversion element was 10%. The transmittance was 74%. Conversion efficiency of a single crystal Si solar cell shielded from light by this photoelectric conversion element was 9.1%. Conversion efficiency of this single crystal Si solar cell without shielding light is 20%. A profile of Na concentrations was examined by SIMS. A portion containing 10²⁰ atoms/cm³ of Na was confirmed in the light absorbing layer. Doping concentrations of Zn and Cd in the light absorbing layer were also measured by SIMS. The Zn concentration at a depth of 15 nm from a boundary surface between the first electrode and the light absorbing layer was 1×10²² (atoms/cm³) while that of Cd was 1×10²¹ (atoms/cm³). The Zn concentration at a depth of 750 nm from the boundary surface between the first electrode and the light absorbing layer was 1×10¹⁹ (atoms/cm³) while that of Cd was 1×10¹⁸ (atoms/cm³).

### Example 20

A lower electrode of a film shape containing ITO-SnO₂ was formed on a quartz glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The thickness of the layer was set to approximately 1500 nm. As a result, CdS diffused in the p-type light absorbing layer by heat diffusion, thereby allowing a region thereof near the lower electrode to be an n-type. Thereafter, molybdenum oxide was subjected to vapor deposition to a thickness of 30 nm. As an upper electrode, indium oxide doped with zinc by 10% was formed to a thickness of 100 nm. A band gap of the light absorbing layer was 1.68 eV while conversion efficiency of the photoelectric conversion element was 5% and the transmittance was 75%. Conversion efficiency of a single crystal Si solar cell shielded from light by this photoelectric conversion element was 9.2%. Conversion efficiency of this single crystal Si solar cell without shielding light is 20%. A profile of Na concentrations was examined by SIMS. A portion containing 10²² atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²¹ (atoms/cm³). The Cd concentration at a depth of 750 nm from the boundary surface between the first electrode and the light absorbing layer was 1×10¹⁹ (atoms/cm³).

### Comparative Example 2

A lower electrode of a film shape containing SiO₂-ITO-SnO₂ was formed on a quartz glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The temperature of forming the film and/or the layer was set at approximately 300° C., thereby suppressed diffusion of CdS to CGS. A layer of CdS thus partially remained between the light absorbing layer and the lower electrode. As a result, CdS diffused in the p-type light absorbing layer by heat diffusion, thereby allowing a region thereof near the lower electrode to be an n-type. Thereafter, molybdenum oxide was subjected to vapor deposition to a thickness of 30 nm. As an upper electrode, indium oxide doped with zinc by 10% was formed to a thickness of 100 nm. A band gap of the light absorbing layer was 1.68 eV while conversion efficiency of the photoelectric conversion element was 5% and the transmittance was 70%. Conversion efficiency of a single crystal Si solar cell shielded from light by this photoelectric conversion element was 9.2%. Conversion efficiency of this single crystal Si solar cell without shielding light is 20. Since the quartz substrate does not contain an alkali metal such as Na or K, this photoelectric conversion element had a low conversion efficiency. A profile of Na concentrations was examined by SIMS. However, no Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²¹ (atoms/cm³). The Cd concentration at a depth of 750 nm from the boundary surface between the first electrode and the light absorbing layer was 1×10¹⁹ (atoms/cm³).

### Comparative Example 3

A lower electrode of a film shape containing SiO₂-ITO was formed on a soda-lime glass substrate of 16 mm in length, 12.5 mm in width, and 1.8 mm in thickness by sputtering in an Ar air flow. The thickness of the lower electrode was set to approximately 250 nm. A film of CdS was grown on the lower electrode to the thickness of 50 nm by a solution growth method, whereon a p-type light absorbing layer was formed by a vapor deposition method at an arbitrary ratio of Cu, Ga, and Se. The temperature of forming the film and/or the layer was set at approximately 300° C., thereby suppressed diffusion of CdS to CGS. A layer of CdS thus partially remained between the light absorbing layer and the lower electrode. As a result, CdS diffused in the p-type light absorbing layer by heat diffusion, thereby allowing a region thereof near the lower electrode to be an n-type. Thereafter, molybdenum oxide was subjected to vapor deposition to a thickness of 30 nm. As an upper electrode, indium oxide doped with zinc by 10% was formed to a thickness of 100 nm. A band gap of the light absorbing layer was 1.68 eV while conversion efficiency of the photoelectric conversion element was 7% and the transmittance was 70%. Conversion efficiency of a single crystal Si solar cell shielded from light by this photoelectric conversion element was 9.2%. A profile of Na concentrations was examined by SIMS. A portion containing 10²¹ atoms/cm³ of Na was confirmed in the light absorbing layer. Doping concentrations of Cd in the light absorbing layer were also measured by SIMS. The Cd concentration at a depth of 15 nm from a boundary surface between the first electrode and the light absorbing layer was 1×10²¹ (atoms/cm³). The Cd concentration at a depth of 750 nm from the boundary surface between the first electrode and the light absorbing layer was 1×10¹⁹ (atoms/cm³).

A part of elements is represented herein only by a symbol of element.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photoelectric conversion element, comprising:
a substrate;
a transparent first electrode on the substrate;
a second electrode; and
a light absorbing layer of a homo-junction type interposed between the first electrode and the second electrode,
wherein the light absorbing layer comprises a p-type region on the second electrode side and an n-type region on the first electrode side,
the n-type region contains an n-type dopant, and
the photoelectric conversion element comprises a boundary surface between the light absorbing layer on the n-type region side and the first electrode.

2. The element according to claim 1, comprising the boundary surface between an entire surface of the light absorbing layer on the n-type region side facing the first electrode and an entire surface of the first electrode facing the light absorbing layer.

3. The element according to claim 1,
wherein X and Y satisfy a relation of X/Y>1 where:
d represents a thickness of the light absorbing layer;
X (atom/cm³) represents a concentration of the n-type dopant at a depth of 0.01d in a direction from the boundary surface in the light absorbing layer toward the second electrode; and
Y (atom/cm³) represents a concentration of the n-type dopant at a depth of 0.5d in the direction from the boundary surface in the light absorbing layer toward the second electrode.

4. The element according to claim 3,
wherein the X and the Y satisfy a relation of X/Y>10.

5. The element according to claim 3,
wherein the X and the Y satisfy a relation of X/Y>100.

6. The element according to claim 1,
wherein a concentration of the n-type dopant at a depth of 0.01d in a direction from the boundary surface in the light absorbing layer toward the second electrode is within 10¹⁹ to 10²¹ (atoms/cm³) where:
d represents a thickness of the light absorbing layer.

7. The element according to claim 1,
wherein X and Z satisfy a relation of X/Z>2 where:
d represents a thickness of the light absorbing layer;
X (atom/cm³) represents a concentration of the n-type dopant at a depth of 0.01d in a direction from the boundary surface in the light absorbing layer toward the second electrode; and
Z (atom/cm³) represents a concentration of the n-type dopant at a depth of 0.1d in the direction from the boundary surface in the light absorbing layer toward the second electrode.

8. The element according to claim 1, further comprising an oxide layer or a metal film between the light absorbing layer and the second electrode.

9. The element according to claim 1,
wherein the n-type dopant contains at least one element selected from the group consisting of; Cd, Zn, and Mg.

10. The element according to claim 1,
wherein the n-type dopant is a metal or a compound containing at least one element selected from the group consisting of; Cd, Zn, and Mg.

11. The element according to claim 1,
wherein the light absorbing layer contains Na, K, or Na and K.

12. The element according to claim 1,
wherein the light absorbing layer includes a region containing Na, K, or Na and K at a concentration within 10¹⁹ atoms/cm³ and 10²² atoms/cm³.

13. A solar cell obtained by using the photoelectric conversion element according to claim 1.

14. A solar cell module obtained by using the solar cell according to claim 13.

15. A solar power generating system adapted to generate electricity using the solar cell module according to claim 14.

16. A photoelectric conversion element using the photoelectric conversion element according to claim 1 as a multifunction-type photoelectric conversion element.

17. A solar cell obtained by using the photoelectric conversion element according to claim 16.

18. A solar cell module obtained by using the solar cell according to claim 17.

19. A solar power generating system adapted to generate electricity using the solar cell module according to claim 18.
